(19) United States
(12) Patent Application Publication
(10) Pub. No.: US 2003/0156446 A1
(43) Pub. Date: Aug. 21, 2003

(54) Integrated memory circuit having storage capacitors which can be written to via word lines and bit lines

(76) Inventors: Herbert Benzinger, Munchen (DE); Stephan Schroder, Munchen (DE); Norbert Wirth, Unterschleissheim (DE)

Correspondence Address: LERNER AND GREENBERG, P.A., POST OFFICE BOX 2480, HOLLYWOOD, FL, 33022-2480, US

(21) Appl. No.: 10/368,332

(22) Filed: Feb. 18, 2003

(30) Foreign Application Priority Data
Feb. 15, 2002 (DE) 102 06 247.1

(51) Int. Cl. G11C 11/24

(52) U.S. Cl. 365/149

(57) ABSTRACT

An integrated memory circuit has first and second storage capacitors, addressed via first and second word lines and first and second bit lines, respectively. The first and second word lines are connected to an address decoder circuit, and the first and second bit lines are connected to a read/write amplifier. The address decoder circuit activates the first and second word lines during a write operation, so that, during the writing of a datum, the read/write amplifier writes the datum to the first memory cell and a complementary datum to the second memory cell. The address decoder circuit activates the first and second word lines during a read operation, so that the charge of the first memory cell flows onto the first bit line and the charge of the second memory cell flows onto the second bit line, the datum to be read out corresponding to the sign of the charge difference.

### BACKGROUND OF THE INVENTION

1. Field of the Invention

The invention relates to an integrated memory circuit having storage capacitors that can be addressed via word lines and can be written to and read from via bit lines. The invention furthermore relates to a method for writing to and for reading from an integrated memory cell.

Dynamic memory cell in DRAMs have a limited data retention time. The data retention time is dependent on the magnitude of the cell capacitance, the bit line capacitance, the temperature and the technologically dictated leakage current paths. If the data retention time is exceeded, the cell information is no longer reliably available. To counteract the loss of cell charge, refresh cycles are performed. The refresh cycles rewrite the information to the cells at predetermined time intervals. The provision of the refresh cycles causes an increased power consumption of the DRAM.

If it is desired to reduce the power consumption of the DRAMs, then it is customary to provide memory cells whose capacitances are increased relative to the conventional memory cells. This reduces the number of refresh cycles in a predetermined period of time, as a result of which the power consumption of the DRAM is reduced. Equally, memory cells with increased storage capacitances are provided if increased requirements are made on the reliability of the integrated memory circuit. However, this requires a new layout of the memory matrix, which is complicated and associated with increased costs.

In particular during the start-up of the production of new memory modules (ramp-up), the production yield is low. The low yield is often a consequence of excessively short data retention times. Usually, memory modules with excessively short data retention times cannot be used since excessively short refresh cycles greatly impair the performance of the entire system.

### SUMMARY OF THE INVENTION

It is accordingly an object of the invention to provide an integrated memory circuit having storage capacitors which can be written to via word lines and bit lines which overcome the above-mentioned disadvantages of the prior art devices and methods of this general type, whose power consumption is reduced and whose reliability is increased. Furthermore, the intention is to make provision that memory modules which should be rejected on account of short data retention times can subsequently be modified in such a way that they satisfy the specifications with regard to the data retention time.

With the foregoing and other objects in view there is provided, in accordance with the invention, an integrated memory circuit. The memory circuit contains word lines including a first word line and a second word line, bit lines including a first bit line and a second bit line, an address decoding circuit connected to the word lines, and a read/write amplifier. The bit lines are connected in pairs to the read/write amplifier. Storage capacitors, including a first storage capacitor and a second storage capacitor, are coupled to and addressed by the word lines and the bit lines. The address decoding circuit activates the first and second word lines during a read and/or write operation. During a write operation of writing a datum, the read/write amplifier is driven so that, through the first bit line, the first storage capacitor addressed by the first word line is occupied by a first charge and, through the second bit line, the second storage capacitor addressed by the second word line is occupied by a second charge. The first charge and the second charge depend on the datum to be written. During a read operation, the first charge of the first storage capacitor flows onto the first bit line and the second charge of the second storage capacitor flows onto the second bit line. The datum to be read out is determined by a charge difference between the first and second bit lines, the charge difference being detected by the read/write amplifier.

The invention relates to an integrated memory circuit having storage capacitors, which can be addressed through word lines and bit lines. The word lines are connected to an address decoder circuit. The bit lines are connected to a read/write amplifier. The address decoder circuit is embodied so as to activate a first and a second word line during a read and/or write operation, in which case, during the operation of writing a datum, the read/write amplifier is driven so that the first storage capacitor is occupied by a first charge and the second storage capacitor is occupied by a second charge. In this case, the first charge and the second charge, i.e. in particular the charge difference between first and second charge, are dependent on the datum to be written. The first charge and the second charge are preferably complementary. During a read operation, the first and second word lines are activated, so that the first charge of the first storage capacitor flows onto the first bit line and the second charge of the second storage capacitor flows onto the second bit line. In this case, the datum to be read out is determined by the charge difference detected by the read/write amplifier, e.g. its sign.

The invention has the advantage that the data retention time of a memory cell can be increased without altering the layout structure of the memory matrix. This is achieved by virtue of the fact that the number of storage capacitances is multiplied for the storage of a datum in that not just one storage capacitance but two or more are used for storing a single specific datum. This is achieved in such a way that the first storage capacitor on the first bit line is occupied by a first, e.g. positive, charge, while the storage capacitor connected on the second bit line is occupied by a second, e.g. negative, charge, or vice versa. In this case, the reference potential for the positive or negative charge is constituted by the potential of the first and second bit lines, i.e. the potential to which the bit line is put before the charges flow onto the bit line from the storage capacitors through activation of the word lines during a read operation.

The read/write amplifier is in each case connected to a first and a second bit line and amplifies a small charge difference between the first and second bit lines for the read-out of the datum. During the writing of a datum, depending on the datum to be written, a positive charge with respect to the initial potential of the bit lines is applied to the first bit line and a negative charge is applied to the second bit line, or vice versa. This is essentially done simultaneously, so that charges are stored in the first and second storage capacitors. This has the effect that the data retention time of the memory cell can be increased at the expense of the memory space available on the memory module.

The invention thus makes it possible, in a very flexible manner, at the expense of the memory size available in the module, to increase the data retention time and thus to reduce the number of refresh cycles per unit of time. A low-power, long-retention module is thus obtained which can be realized without changing the layout of the memory matrix from a standard module.

Furthermore, the memory circuit according to the invention can be used for applications with increased reliability requirements with regard to soft error rate or degradation behavior.

Particularly during the start-up of a production of memory modules, a low yield is attained, often caused by short data retention times of the memory cells. Defective memory modules on account of short data retention times are usually irreparable and should therefore be rejected. The memory circuit according to the invention makes it possible in this case to render the memory modules utilizable by reducing the memory space and increasing the data retention time. By way of example, 256 MB modules can thus be modified by reprogramming to form 128 MB modules, which would otherwise have to be rejected.

It may be provided that the address decoder circuit has an input for a control signal in order to receive a control signal. Depending on the control signal, the first and second word lines are addressed individually or jointly. This has the advantage that it is possible to control whether the address decoder circuit is operated in a conventional manner, namely by individual activation of the word lines, or in a manner such that the first and second word lines are activated jointly.

It may furthermore be provided that a plurality of first word lines with first storage capacitors and a plurality of second word lines with second storage capacitors are provided. The first and second word lines may be jointly addressable. The first storage capacitors are connected to the first bit line and the second storage capacitors are connected to the second bit line. During a read operation, the first charges of the first storage capacitors flow onto the first bit line and the second charges of the second storage capacitors flow onto the second bit line. During an operation of writing a datum, the read/write amplifier is driven so that the first storage capacitors are occupied by first charges and the second storage capacitors are occupied by second charges. The first charges and the second charges are chosen in a manner dependent on the datum to be written. In this way, it is possible to increase the data retention time virtually arbitrarily by increasing the number of first storage capacitors and/or second storage capacitors.

Preferably, an integrated memory circuit is provided which has a plurality of further word lines with further storage capacitors and/or a plurality of further bit lines. For the addressing of the further storage capacitors, in each case only one of the further word lines is simultaneously activated. In this way, it is possible to provide a memory module which has memory cells with an increased data retention time and memory cells with a normal data retention time, i.e. memory cells which use only one storage capacitor for storing a datum. As a result, memory cells that defectively have an excessively short data retention time can be repaired by joint addressing with one or more further storage capacitors.

It may preferably be provided that the address decoder circuit is configured to be programmable, so that, as a result of the programming, specific storage capacitors are jointly addressable and the remaining storage capacitors are individually addressable via the word lines. The programming of the address decoder circuit can be performed for example via internal setting memories, such as e.g. hard fuses, or by external terminals of the memory circuit. It is thus possible that when an address is present at inputs of the address decoder circuit, the address decoder circuit identifies whether the memory cell that is to be addressed by the address is a normal memory cell or a memory cell with an increased data retention time.

A further aspect of the present invention provides a method for writing a datum to an integrated memory circuit. To that end, a first and a second word line of the integrated memory circuit are activated, so that a first storage capacitor is connected to a first bit line and a second storage capacitor is connected to a second bit line. Afterward, a datum to be written in is written simultaneously via the first bit line to the first storage capacitor and the second bit line to the second storage capacitor, the first storage capacitor being occupied by a first charge and the second storage capacitor being occupied by a second charge.

A further aspect of the present invention provides a method for reading out a datum from an integrated memory circuit. To that end, first the first and second word lines of the integrated memory circuit are activated, so that the first charge of the first storage capacitor is connected to the first bit line and the second charge of the second storage capacitor is connected to the second bit line, so that the charges flow onto the bit lines. Afterward, the charge difference between the charge of the first bit line and the charge of the second bit line is detected, the charge difference between the first and second charges determines the value of the datum, e.g. by way of the sign of the charge difference.

The methods according to the invention have the advantage that a plurality of storage capacitors are used for storing a datum, so that the capacitance for storing the charge corresponding to the datum is doubled or multiplied.

Other features which are considered as characteristic for the invention are set forth in the appended claims.

Although the invention is illustrated and described herein as embodied in an integrated memory circuit having storage capacitors which can be written to via word lines and bit lines, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a block diagram of a preferred embodiment of a memory cell according to the invention;

FIG. 2 is a graph in which the number of defects of a conventional DRAM and of a memory module according to the invention is plotted against data retention time;

FIG. 3 is a graph in which the data retention time of a conventional DRAM and a memory module according to the invention is plotted against temperature; and

FIG. 4 is a graph in which a ratio data retention times of a memory module according to the invention to a conventional DRAM is plotted against the temperature.

### DESCRIPTION OF THE PREFERRED EMBODIMENTS

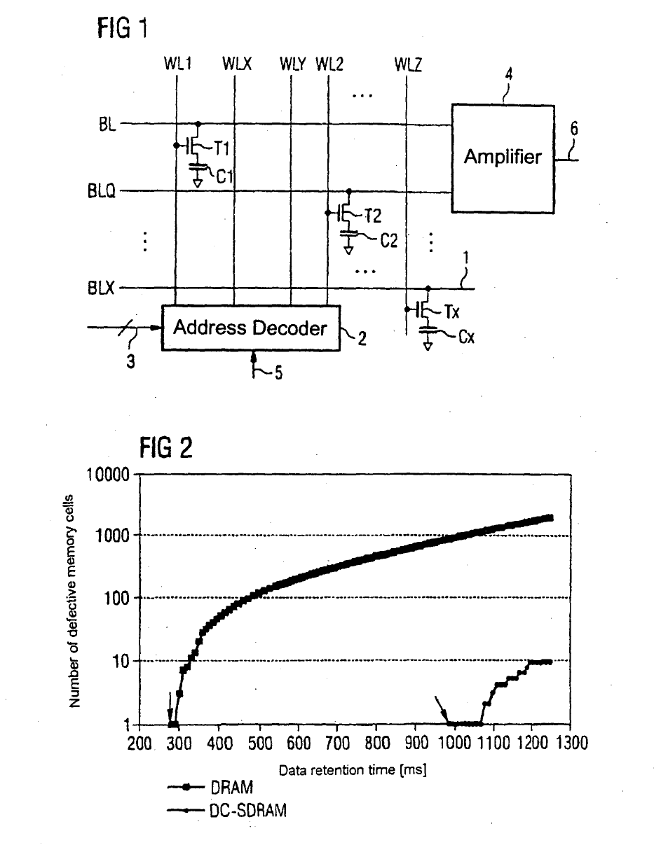

Referring now to the figures of the drawing in detail and first, particularly, to FIG. 1 thereof, there is shown in a block diagram, a partial detail from the memory circuit according to the invention, which is configured for example as a dynamic memory module (DRAM).

Customary DRAM memory modules have a multiplicity of word and bit lines. The word lines can be driven via an address decoding circuit. During the reading of a memory cell, in each case one of the word lines is activated, so that a charge of a storage capacitor connected thereto flows onto an associated bit line. The bit lines are connected in pairs to a read/write amplifier, via which the charge difference on the bit lines is detected and amplified. During writing, a potential is applied to a bit line and the corresponding storage capacitor is activated via an activated word line, so that the charge is stored.

FIG. 1 shows a memory circuit 1 with an address decoding circuit 2. The address decoding circuit 2 has address inputs 3 on which address signals can be applied. The address signals specify the address from which data are to be read or to which data are to be written. The address decoding circuit 2 drives a multiplicity of word lines WL1, WL2, WLX, WLY, WLZ, including a first word line WL1 and a second word line WL2. A multiplicity of word lines are connected to the address decoding circuit 2.

The first word line WL1 is connected to a gate of a first memory transistor T1, and the second word line WL2 is connected to a gate of a second memory transistor T2. A drain/source terminal of the first memory transistor T1 is connected to a first bit line BL, and a drain/source terminal of a second memory transistor T2 is connected to a second bit line BLQ. A second source/drain terminal of the first memory transistor T1 is connected to a first terminal of a first storage capacitor C1, and a second terminal of the first storage capacitor C1 is connected to ground or some other fixed potential. A second source/drain terminal of the second memory transistor T2 is connected to a first terminal of a second storage capacitor C2. A second terminal of the second storage capacitor C2 is connected to ground or a defined voltage potential.

A read/write amplifier 4 is connected to the first bit line BL and to the second bit line BLQ.

The address decoding circuit 2 has a control input 5, at which a control signal is present. The control signal specifies whether the memory cell, the memory cell addressed by the address present at the address input 3, is to be formed by one storage capacitor or two storage capacitors.

If a memory cell is to be formed by two storage capacitors C1, C2, then the control signal is applied via the control line 5. Upon application to the address corresponding to the storage capacitors C1, C2, the first and second word lines WL1, WL2 are activated and the first memory transistor T1 and the second memory transistor T2 are turned on in this way, so that the first terminals of the first and second storage capacitors C1, C2 are coupled to the respective bit line.

During a write operation, the read/write amplifier 4 receives a datum via a data line 6. The datum is converted into a potential difference on the first bit line and the second bit line BL, BLQ. As a result, the first storage capacitor C1 is charged to a first potential, e.g. a positive potential, and the second storage capacitor C2 is charged to a second potential, e.g. a negative potential. The positive potential and the negative potential are related to a central voltage potential to which the first and second bit lines BL, BLQ are charged before each write or read operation.

During a read-out operation, through activation of the first word line WL1 and the second word line WL2, the charge of the first storage capacitor C1 flows onto the first bit line BL and the charge of the second storage capacitor C2 flows via the second memory transistor T2 onto the second bit line BLQ. Since the first storage capacitor C1 and the second storage capacitor C2 have been charged, during the writing process, with an opposite charge with respect to the bit line potentials, the charge difference which now occurs between the first bit line BL and the second bit line BLQ is larger than would be the case if only one of the storage capacitors effected the charge difference. Since a larger charge difference between the first bit line BL and the second bit line BLQ needs a longer time to be dissipated by leakage currents, the charge difference can be detected more certainly by the read/write amplifier 4. Consequently, the storage and the read-out of a datum which is stored with the aid of two storage capacitors are more reliable.

The data retention time of a memory cell is determined by what quantity of charge is stored in the storage capacitance and the total resistance with which the leakage current paths oppose the flowing away of the charge from the storage capacitance. The data retention time can thus be increased by doubling or by multiplying the charge difference that is to be detected by the read/write amplifier.

By using a virtually arbitrary number of first or second storage capacitors C1, C2, the data retention time can thus be increased virtually arbitrarily over a large range.

The address decoder circuit may be provided such that it automatically identifies, e.g. using a programming in a memory situated in it, which of the addresses present is formed by more than one storage capacitor and which of the memory cells addressed by the address is formed just by one storage capacitor. Thus, the address decoder circuit 2 may have a plurality of word lines that are activated simultaneously during the interrogation of a first address and are activated individually during the writing-in or read-out of a second address.

FIG. 2 illustrates a graph illustrating the improvement in performance of the memory circuit according to the invention relative to a conventional DRAM. The test was carried out using a 256 MB memory to which an X stripe pattern is written. During the reading process, via the test modes, the sense amplifier is deactivated and two word lines are activated sequentially, so that a charge equalization of cells with inverse physical charges is effected between the first bit line and the second bit line. The sense amplifier is subsequently activated by a DSEL command. The precharging of the bit lines is carried out via a test mode/exit command. This simulates the behavior of an SDRAM in which a memory cell on the first bit line BL and the second bit line BLQ with inverse physical charges is simulated simultaneously by use of two word lines.

In the graph, the number of defective memory cells is plotted against the data retention time and it is evident that the first defect for the data retention time in the case of a conventional DRAM memory module already occurs at a data retention time of less than 300 msec. In contrast, when storing a datum in a memory cell formed by two storage capacitors in the case of the memory module according to the invention, the first defect only occurs at about 1000 msec. It is evident that the data retention time can be multiplied by using a memory circuit according to the invention.

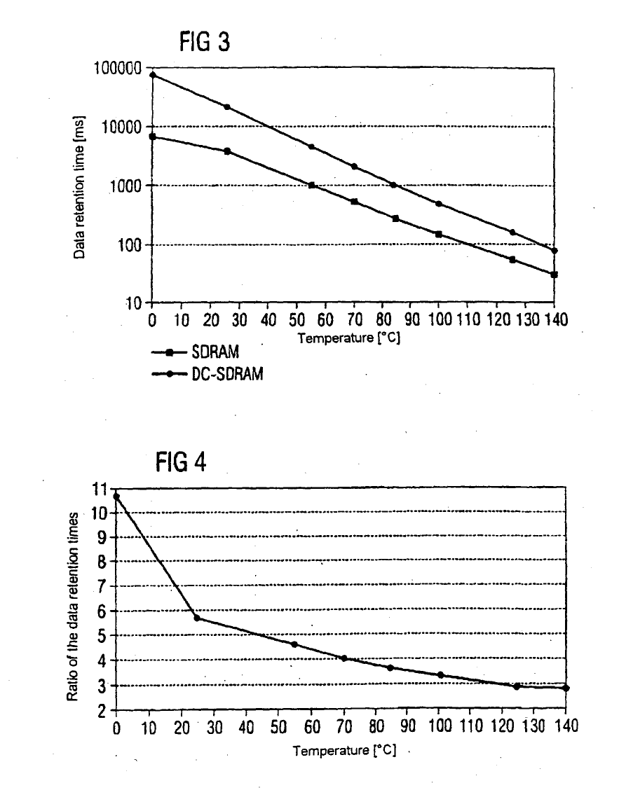

In FIG. 3, the data retention time of a conventional DRAM memory module and of a memory module according to the invention is plotted against the temperature. It is evident that the data retention time in the case of the memory module according to the invention is considerably increased relative to the data retention time of a conventional SDRAM memory module over the entire temperature range between 0 and 140° C.

A ratio of the data retention time against temperature is illustrated in FIG. 4. It is evident that the data retention time in the case of the memory module according to the invention is at least a factor of 3 longer than in the case of the conventional DRAM memory module.

We claim:

1. An integrated memory circuit, comprising:
word lines including a first word line and a second word line;
bit lines including a first bit line and a second bit line;
an address decoding circuit connected to said word lines;
a read/write amplifier, said bit lines connected in pairs to said read/write amplifier; and
storage capacitors, including a first storage capacitor and a second storage capacitor, coupled to and addressed by said word lines and said bit lines;
said address decoding circuit activating said first and second word lines during a read and/or write operation, in which case during a write operation of writing a datum, said read/write amplifier being driven so that, through said first bit line, said first storage capacitor addressed by said first word line being occupied by a first charge and, through said second bit line, said second storage capacitor addressed by said second word line being occupied by a second charge, the first charge and the second charge depending on the datum to be written, during a read operation, the first charge of said first storage capacitor flows onto said first bit line and the second charge of said second storage capacitor flows onto said second bit line, the datum to be read out being determined by a charge difference between said first and second bit lines, the charge difference being detected by said read/write amplifier.

2. The integrated memory circuit according to claim 1, wherein said address decoding circuit has an input for receiving a control signal, said address decoding circuit addressing said first and second word lines individually or jointly, depending on the control signal, during the write operation and/or during the read operation.

3. The integrated circuit according to claim 1, wherein the first charge and the second charge are complementary to one another.

4. The integrated memory circuit according to claim 1, wherein:
said first word line addressing said first storage capacitor is one of a plurality of first word lines coupled to first storage capacitors; and
said second word line addressing said second storage capacitor is one of and a plurality of second word lines coupled to second storage capacitors, said first and second word lines being jointly addressable, said first storage capacitors being coupled to said first bit line and said second storage capacitors being coupled to said second bit line, in which case, during the read operation, first charges of said first storage capacitors flow onto said first bit line and second charges of said second storage capacitors flow onto said second bit line, and, during the write operation of writing the datum, said read/write amplifier is driven so that said first storage capacitors are occupied by the first charges and said second storage capacitors are occupied by the second charges, the first charges and the second charges being dependent on the datum to be written.

5. The integrated memory circuit according to claim 1, further comprising:
a plurality of further storage capacitors;
a plurality of further bit lines coupled to said further storage capacitors; and
a plurality of further word lines addressing said further storage capacitors, and during addressing of said further storage capacitors, in each case only one of said further word lines is simultaneously activated.

6. The integrated memory circuit according to claim 5, wherein said address decoding circuit is programmable, so that, as a result of programming, specific ones of said storage capacitors are jointly addressable and remaining ones of said storage capacitors are individually addressable via said word lines.

7. The integrated memory circuit according to claim 1, wherein during addressing of said storage capacitors, in each case only one further one of said word lines is simultaneously activated.

8. The integrated memory circuit according to claim 7, wherein said address decoding circuit is programmable, so that, as a result of programming, specific ones of said storage capacitors are jointly addressable and remaining ones of said storage capacitors are individually addressable via said word lines.

9. A method for storing a datum in an integrated memory circuit, which comprises the steps of:
activating a first and a second word line of the integrated memory circuit, resulting in a first storage capacitor being coupled to a first bit line and a second storage capacitor being coupled to a second bit line; and
simultaneously writing the datum to be written in through the first bit line to the first storage capacitor and in through the second bit line to the second storage capacitor, resulting in the first storage capacitor being charged with a first charge and the second storage capacitor being charged with a second charge.

10. The method according to claim 9, further comprising the step of activating the first and second word lines during addressing of a first memory cell and only one of the first and the second word line being addressed during addressing of a second memory cell.

11. The method according to claim 9, further comprising the step of activating the first and second word lines during addressing of a first memory cell and only a further word line being addressed during addressing of a second memory cell.

12. A method for reading out a datum from an integrated memory circuit, which comprises the steps of:
activating a first and a second word line of the integrated memory circuit, resulting in a first charge of a first storage capacitor being impressed on a first bit line and a second charge of a second storage capacitor being impressed on a second bit line; and
detecting a charge difference between the first charge on the first bit line and the second charge on the second bit line, the charge difference determining a value of the datum.

13. The method according to claim 12, further comprising the step of activating the first and second word lines during addressing of a first memory cell and only one of the first and the second word line being addressed during addressing of a second memory cell.

14. The method according to claim 12, further comprising the step of activating the first and second word lines during addressing of a first memory cell and only a further word line being addressed during addressing of a second memory cell.
